(19) United States
(12) Patent Application Publication
(10) Pub. No.: US 2021/0242127 A1
(43) Pub. Date: Aug. 5, 2021

(54) BACK-END-OF-LINE (BEOL) SIDEWALL METAL-INSULATOR-METAL (MIM) CAPACITOR

(71) Applicant: QUALCOMM Incorporated, San Diego, CA (US)

(72) Inventors: Sinan GOKTEPELI, San Diego, CA (US); Farid AZZAZY, Laguna Niguel, CA (US); Ravi Pramod Kumar VEDULA, San Diego, CA (US)

(21) Appl. No.: 16/779,192

(22) Filed: Jan. 31, 2020

(51) Int. Cl. H01L 23/522; H01L 49/02

(52) U.S. Cl. CPC H01L 23/5223; H01L 28/60

(57) ABSTRACT

An integrated circuit (IC) is described. The IC includes a substrate and a plurality of back-end-of-line (BEOL) layers on the substrate. The IC also includes a trench having tapered sidewalls and a base in a BEOL layer of the plurality of BEOL layers on the substrate. The IC further includes a metal-insulator-metal (MIM) capacitor on the tapered sidewalls and the base of the trench in the BEOL layer. The MIM capacitor includes a first conductive layer to line the tapered sidewalls and the base of the trench. The MIM capacitor also includes a dielectric layer to line the first conductive layer on the tapered sidewalls and the base of the trench. The MIM capacitor further includes a second conductive layer on the dielectric layer and filling the trench in the BEOL layer.

### BACKGROUND

### Field

Aspects of the present disclosure relate to semiconductor devices and, more particularly, to a back-end-of-line (BEOL) sidewall metal-insulator-metal (MIM) capacitor.

### Background

Mobile radio frequency (RF) chips (e.g., mobile RF transceivers) have migrated to a deep sub-micron process node due to cost and power consumption considerations. Designing mobile RF transceivers is further complicated by added circuit functions for supporting communication enhancements, such as fifth generation (5G) communication systems. Further design challenges for mobile RF transceivers include using passive devices, which directly affect analog/RF performance considerations, including mismatch, noise, and other performance considerations.

Passive devices may involve high performance capacitor components. For example, analog integrated circuits use various types of passive devices, such as integrated capacitors. These integrated capacitors may include metal-oxide-semiconductor (MOS) capacitors, p-n junction capacitors, metal-insulator-metal (MIM) capacitors, poly-to-poly capacitors, metal-oxide-metal (MOM) capacitors, and other like capacitor structures.

The design of mobile RF transceivers may include MIM capacitors and/or MOM capacitors. Unfortunately, conventional MIM capacitors may exhibit breakdown voltages and quality (Q)-factors that are insufficient for RF products, such as RF transceivers. Conversely, MOM capacitors offer improved breakdown voltages and Q-factors relative to MIM capacitors, but at the cost of lower density. External capacitors offer a solution, but at a significant cost, while involving packaging issues. A high density capacitor having an increased breakdown voltage and a high Q-factor is desired.

### SUMMARY

An integrated circuit (IC) is described. The IC includes a substrate and a plurality of back-end-of-line (BEOL) layers on the substrate. The IC also includes a trench having tapered sidewalls and a base in a BEOL layer of the plurality of BEOL layers on the substrate. The IC further includes a metal-insulator-metal (MIM) capacitor on the tapered sidewalls and the base of the trench in the BEOL layer. The MIM capacitor includes a first conductive layer to line the tapered sidewalls and the base of the trench. The MIM capacitor also includes a dielectric layer to line the first conductive layer on the tapered sidewalls and the base of the trench. The MIM capacitor further includes a second conductive layer on the dielectric layer and filling the trench in the BEOL layer.

A method for fabricating a back-end-of-line (BEOL) sidewall metal-insulator-metal (MIM) capacitor is described. The method includes etching a BEOL layer of a plurality of BEOL layers on a substrate to form a trench having tapered sidewalls and a base. The method also includes depositing a first conductive layer on the tapered sidewalls and the base of the trench. The method further includes depositing a dielectric layer on the first conductive layer to line the tapered sidewalls and the base of the trench. The method also includes depositing a second conductive layer on the dielectric layer to fill the trench in the BEOL layer. The method further includes fabricating a pair of capacitor terminals coupled to the first conductive layer and the second conductive layer.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a cross-section illustrating an integrated circuit (IC) device including an interconnect stack that contains conventional metal-oxide-metal (MOM) capacitor structures.

FIG. 2 is a block diagram illustrating a radio frequency integrated circuit (RFIC) chip having a back-end-of-line (BEOL) metal-insulator-metal (MIM) capacitor.

FIG. 3 is a block diagram illustrating a radio frequency integrated circuit (RFIC) chip having a back-end-of-line (BEOL) sidewall metal-insulator-metal (MIM) capacitor (SMC), according to aspects of the present disclosure.

FIG. 4 is a diagram illustrating a back-end-of-line (BEOL) sidewall metal-insulator-metal (MIM) capacitor (SMC), according to aspects of the present disclosure.

FIGS. 5A-5C are diagrams showing a process of fabricating the BEOL sidewall MIM capacitor of FIG. 4, according to aspects of the present disclosure.

FIGS. 6A-6C are diagrams further illustrating the process of fabricating the BEOL sidewall MIM capacitor of FIG. 4, according to aspects of the present disclosure.

FIGS. 7A-7C are diagrams further illustrating the process of fabricating the BEOL sidewall MIM capacitor of FIG. 4, according to aspects of the present disclosure.

FIG. 8 is a process flow diagram illustrating a method for fabricating a back-end-of-line (BEOL) sidewall metal-insulator-metal (MIM) capacitor, according to an aspect of the present disclosure.

FIG. 9 is a block diagram showing an exemplary wireless communication system in which a configuration of the present disclosure may be employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Mobile radio frequency (RF) chips (e.g., mobile RF transceivers) have migrated to a deep sub-micron process node due to cost and power consumption considerations. Designing mobile RF transceivers is complicated by added circuit functions for supporting communication enhancements, such as fifth generation (5G) communication systems. Further design challenges for mobile RF transceivers include using passive devices, which directly affect analog/RF performance considerations, including mismatch, noise, and other performance considerations.

Passive devices in mobile RF transceivers may include high performance capacitor components. For example, analog integrated circuits use various types of passive devices, such as integrated capacitors. These integrated capacitors may include metal-oxide-semiconductor (MOS) capacitors, p-n junction capacitors, metal-insulator-metal (MIM) capacitors, poly-to-poly capacitors, metal-oxide-metal (MOM) capacitors, and other like capacitor structures. Capacitors are generally passive elements used in integrated circuits for storing an electrical charge. For example, parallel plate capacitors are often made using plates or structures that are conductive with an insulating material between the plates. The amount of storage, or capacitance, for a given capacitor is contingent upon the materials used to make the plates and the insulator, the area of the plates, and the spacing between the plates. The insulating material is often a dielectric material.

These parallel plate capacitors consume a large area on a semiconductor chip because many designs place the capacitor over the substrate of a chip. Unfortunately, this approach reduces the available area for active devices.

Various aspects of the present disclosure provide a back-end-of-line (BEOL) sidewall metal-insulator-metal (MIM) capacitor. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms chip and die may be used interchangeably.

As described, the back-end-of-line interconnect layers may refer to the conductive interconnect layers (e.g., a first interconnect layer (M1) or metal one M1, metal two (M2), metal three (M3), metal four (M4), etc.) for electrically coupling to front-end-of-line active devices of an integrated circuit. The various back-end-of-line interconnect layers are formed at corresponding back-end-of-line interconnect levels, in which lower back-end-of-line interconnect levels use thinner metal layers relative to upper back-end-of-line interconnect levels. The back-end-of-line interconnect layers may electrically couple to middle-of-line interconnect layers, for example, to connect M1 to an oxide diffusion (OD) layer of an integrated circuit. The middle-of-line interconnect layer may include a zero interconnect layer (M0) for connecting M1 to an active device layer of an integrated circuit. A back-end-of-line first via (V2) may connect M2 to M3 or others of the back-end-of-line interconnect layers.

Aspects of the present disclosure describe a BEOL sidewall MIM capacitor, having an improved breakdown voltage as well as an improved Q-factor, sufficient for RF products, such as RF transceivers. For example, an integrated circuit (IC) includes a substrate and back-end-of-line (BEOL) layers on the substrate. In one configuration, the IC includes a trench having tapered sidewalls and a base in a BEOL layer of the BEOL layers on the substrate. In one aspect of the present disclosure, a BEOL sidewall metal-insulator-metal (MIM) capacitor is formed on the tapered sidewalls and the base of the trench in the BEOL layer. The BEOL sidewall MIM capacitor may be composed of a first conductive layer lining the tapered sidewalls and the base of the trench. The BEOL sidewall MIM capacitor also includes a dielectric layer lining the first conductive layer on the tapered sidewalls and the base of the trench. The BEOL sidewall MIM capacitor further includes a second conductive layer on the dielectric layer filling the trench in the BEOL layer. The tapering improves reliability.

According to aspects of the present disclosure, a BEOL sidewall MIM capacitor (SMC) is described. In aspects of the present disclosure, the sidewall MIM capacitor is defined using a sidewall of ultra-thick conductive layers (e.g., metals). As described herein, ultra-thick conductive layers refer to conducive layers (e.g., metals) having a predetermined thickness (e.g., about 3.0 to 3.5 microns thick), depending on the foundry. A sidewall MIM capacitor process may involve two masks, which is the same number of masks to fabricate conventional MIM capacitors. The presence of ultra-thick conductive layers (e.g., a metal of 3.0 microns) ensures a good quality (Q)-factor.

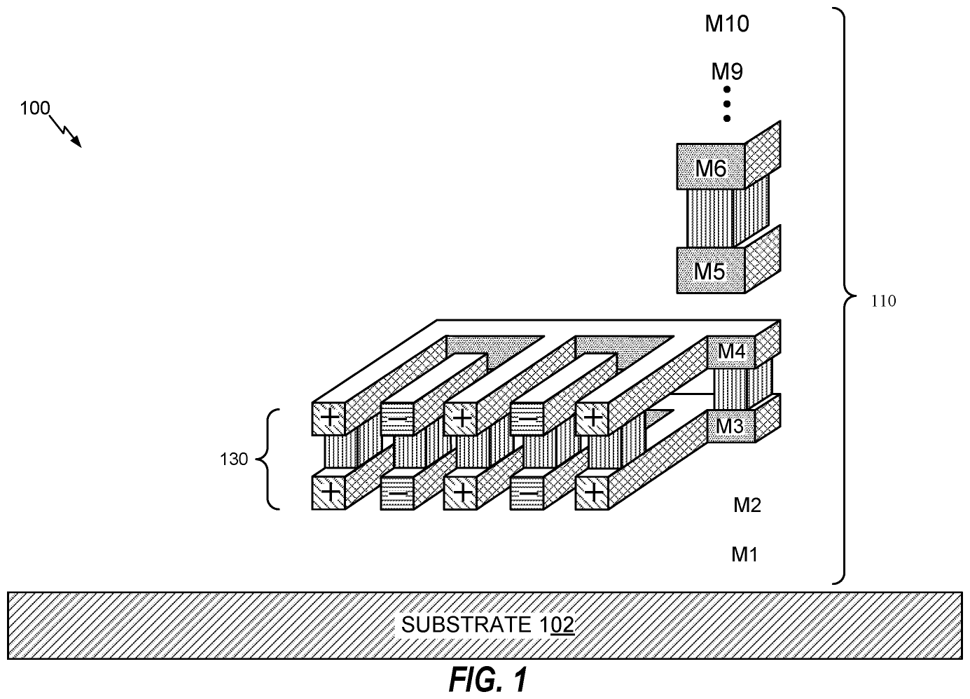

FIG. 1 is a block diagram illustrating a cross-section of an analog integrated circuit (IC) device 100 including an interconnect stack 110. The interconnect stack 110 of the IC device 100 includes multiple BEOL conductive interconnect layers (M1, . . . , M9, M10) on a semiconductor substrate (e.g., a diced silicon wafer) 102. The semiconductor substrate 102 supports a metal-oxide-metal (MOM) capacitor 130. In this example, the MOM capacitor 130 is formed in the M3 and M4 interconnect layers, below the M5 and M6 interconnect layers. The MOM capacitor 130, which is formed from lateral conductive fingers of different polarities, may offer an improved breakdown voltage (e.g., voltage to breakdown (VBD)) and an improved quality (Q)-factors relative to a MIM capacitor. The improved breakdown voltage and Q-factor of the MOM capacitor 130, however, come at the cost of lower density. Conversely, conventional MIM capacitors may exhibit breakdown voltages and Q-factors that are insufficient for RF products, such as an RFIC chip. A high density capacitor having an increased breakdown voltage and a high Q-factor is desired.

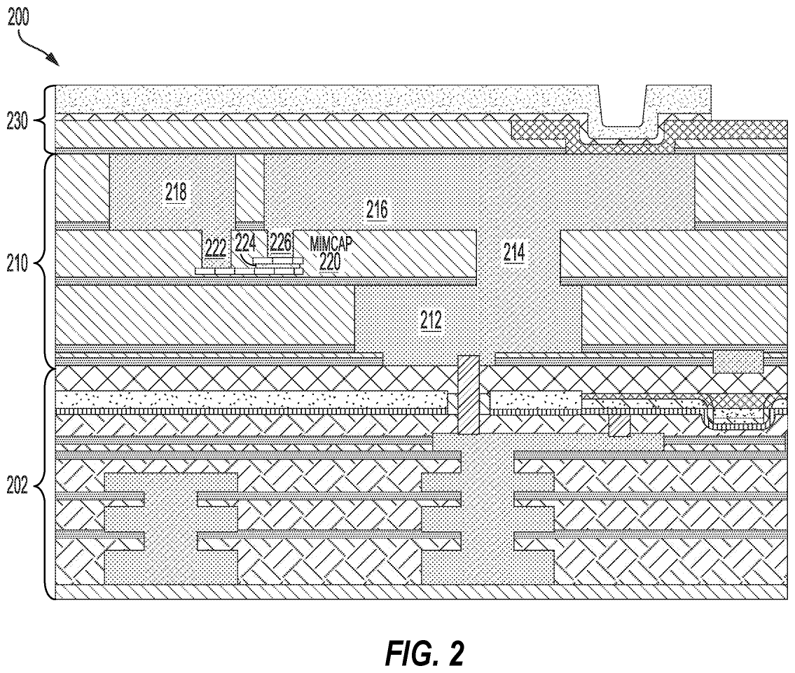

FIG. 2 is a block diagram illustrating a radio frequency integrated circuit (RFIC) chip having a BEOL MIM capacitor. Representatively, an RFIC chip 200 includes a substrate 202 having back-end-of-line (BEOL) layers 210 on the substrate 202 and a redistribution layer (RDL) 230 on the BEOL layers 210. The BEOL layers 210 include a first BEOL interconnect layer 212 (e.g., metal one (M1)) coupled to a first BEOL interconnect via 214 (e.g., V1). In addition, a second BEOL interconnect layer 216 is coupled to the first BEOL interconnect via 214. In this configuration, a MIM capacitor 220 is formed in the BEOL layers 210. The MIM capacitor 220 includes a first terminal 222 (e.g., a bottom electrode), a MIM dielectric layer 224, and a second terminal 226 (e.g., top electrode) on the MIM dielectric layer 224. In addition, another second BEOL interconnect layer 218 is coupled to the first terminal 222 of the MIM capacitor 220. Similarly, the second BEOL interconnect layer 216 is coupled to the second terminal 226 of the MIM capacitor 220.

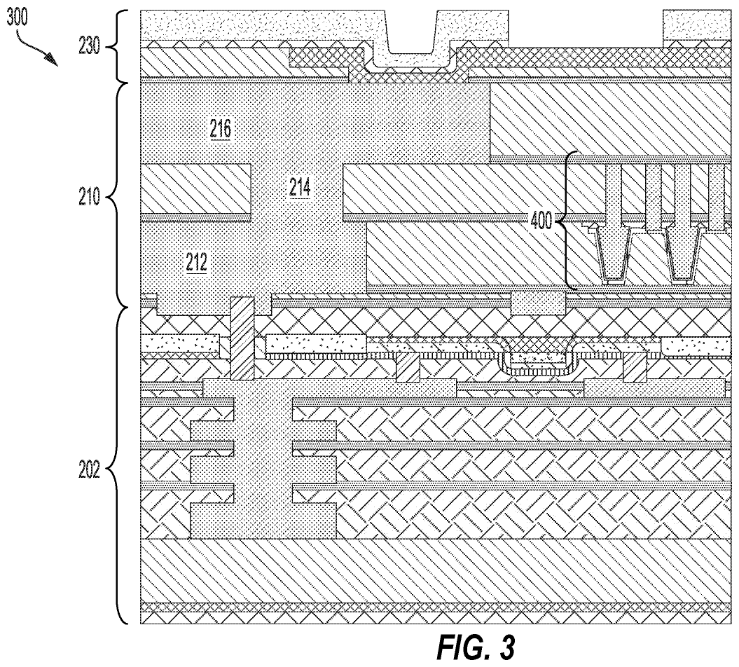

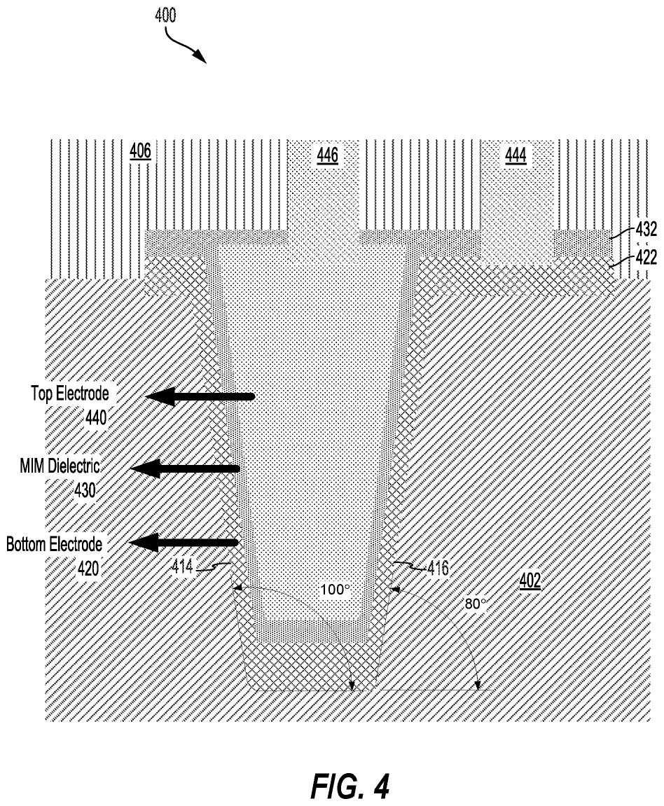

FIG. 3 is a diagram illustrating an RFIC chip 300 having a BEOL sidewall MIM capacitor (SMC), according to aspects of the present disclosure. The RFIC chip 300 shown in FIG. 3 is similar to the RFIC chip 200 shown in FIG. 2, including the substrate 202 having the BEOL layers 210 on the substrate 202 and the RDL 230 on the BEOL layers 210. The BEOL layers 210 also include the first BEOL interconnect layer 212 coupled to the second BEOL interconnect layer 216 through the first BEOL interconnect via 214. In this aspect of the present disclosure, a BEOL sidewall MIM capacitor 400 is integrated within the BEOL layers 210, as further illustrated in FIG. 4.

FIG. 4 is a diagram illustrating a BEOL sidewall MIM capacitor (SMC), according to aspects of the present disclosure. In this configuration, the BEOL sidewall MIM capacitor 400 is formed in an interlayer dielectric (ILD) 402 of the BEOL layers 210, for example, as shown in FIG. 3. The BEOL sidewall MIM capacitor 400 includes a first conductive layer 420 (e.g., a bottom electrode), a MIM dielectric layer 430, and a second conductive layer 440 (e.g., top electrode) on the MIM dielectric layer 430. In addition, a first terminal 444 is coupled to a portion 422 of the first conductive layer 420 through a portion 432 of the MIM dielectric layer 430 on a surface of the ILD 402. A second terminal 446 is coupled to the second conductive layer 440 of the BEOL sidewall MIM capacitor 400.

In one configuration, an inter-metal dielectric (IMD) layer 406 (e.g., a dielectric protection layer) is deposited on the surface of the ILD 402, the portion 432 of the MIM dielectric layer 430, the first terminal 444, and the second terminal 446 to complete the BEOL sidewall MIM capacitor 400. In this configuration, the BEOL sidewall MIM capacitor 400 is formed with tapered sidewalls, which are shown as a first tapered sidewall 414 and a second tapered sidewall 416. In this example, the first tapered sidewall 414 is shown with an angle of one-hundred degrees (100°), and the second tapered sidewall 416 is shown with an angle of eighty degrees (80°). In aspects of the present disclosure, the angle of the first tapered sidewall 414 is in a range of one-hundred degrees (100°) to one-hundred ten degrees (110°), and the angle of the second tapered sidewall 416 is in a range of seventy degrees (70°) to eighty degrees (80°). It should be recognized, however, that other angles for the first tapered sidewall 414 and the second tapered sidewall 416 are contemplated according to aspects of the present disclosure.

In this configuration of the BEOL sidewall MIM capacitor 400, the second conductive layer 440 is composed of a conductive plug having a first portion within the ILD 402. In one configuration, the first portion of the conductive plug (e.g., top electrode) is surrounded by the first conductive layer 420 (e.g. bottom electrode) and the MIM dielectric layer 430. The conductive plug further includes a second portion composed of the second conductive layer 440, which protrudes outside the ILD 402 to which the second terminal 446 is coupled. In this example, a volume of the second conductive layer 440 (e.g., top electrode) is greater than the volume of the first conductive layer 420 (e.g., bottom electrode) of the BEOL sidewall MIM capacitor 400.

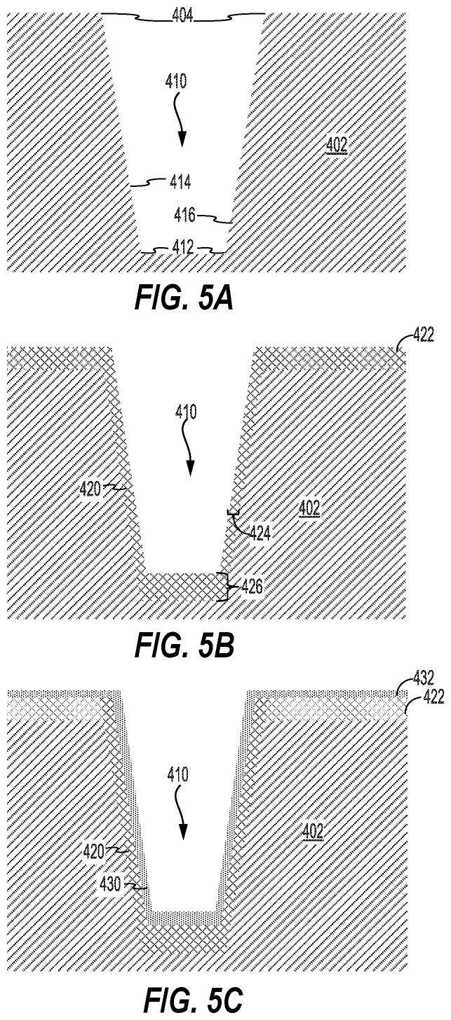

FIGS. 5A-5C are diagrams showing a process of fabricating the BEOL sidewall MIM capacitor 400 of FIG. 4, according to aspects of the present disclosure.

FIG. 5A is a cross-section view of the ILD 402 of the BEOL sidewall MIM capacitor 400 (e.g., SMC) of FIG. 4, according to aspects of the present disclosure. In this configuration, a trench 410 is formed through an opening 404 in the ILD 402 of the BEOL layers 210, for example, as shown in FIG. 3. The trench 410 may be formed by etching the ILD 402 according to a deposited SMC mask (not shown). In this configuration, the trench 410 includes a base 412, the first tapered sidewall 414, and the second tapered sidewall 416. In this example, the angle of the first tapered sidewall 414 and the angle of the second tapered sidewall 416 match the angles shown in FIG. 4. It should be recognized that other angles for the first tapered sidewall 414 and the second tapered sidewall 416 are contemplated according to aspects of the present disclosure.

FIG. 5B further illustrates fabrication of the BEOL sidewall MIM capacitor 400 of FIG. 4, according to aspects of the present disclosure. In FIG. 5B, the first conductive layer 420 is deposited on the first tapered sidewall 414 and the second tapered sidewall 416 as well as the base 412 of the trench 410. A portion 422 of the first conductive layer 420 is deposited on the surface of the ILD 402. The first conductive layer 420 may be formed according to an aluminum bottom plate deposition; however, it should be recognized that other conductive materials are contemplated for depositing the first conductive layer 420. In this configuration, a width 424 of the first conductive layer 420 on the tapered sidewalls (e.g., 414 and 416) is less than the width 426 of the first conductive layer 420 on the base 412 of the trench 410. For example, the width 424 of the first conductive layer 420 on the tapered sidewalls (e.g., 414 and 416) may be 0.15 microns.

FIG. 5C further illustrates fabrication of the BEOL sidewall MIM capacitor 400 of FIG. 4, according to aspects of the present disclosure. In FIG. 5C, the MIM dielectric layer 430 is deposited on the first conductive layer 420 that is on the tapered sidewalls (e.g., 414 and 416) and the base 412 of the trench 410. A portion 432 of the MIM dielectric layer 430 is deposited on the portion 422 of the first conductive layer 420. The MIM dielectric layer 430 may be deposited with a predetermined thickness (e.g., in the range of 0.1 to 0.12 microns for a 60 volt (V) voltage at breakdown (VBD)); however, it should be recognized that other dielectric thicknesses are contemplated for depositing the MIM dielectric layer 430.

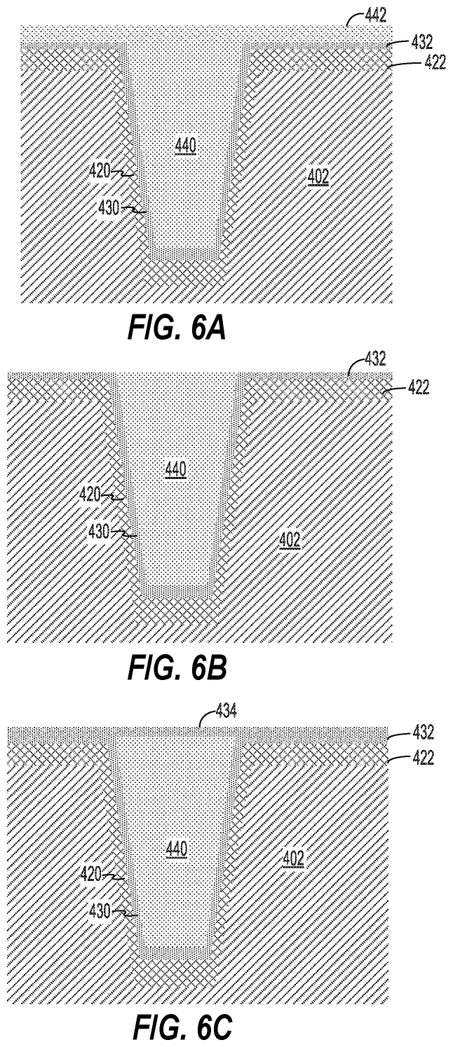

FIGS. 6A-6C are diagrams further illustrating the process of fabricating the BEOL sidewall MIM capacitor of FIG. 4, according to aspects of the present disclosure.

FIG. 6A further illustrates fabrication of the BEOL sidewall MIM capacitor 400 of FIG. 4, according to aspects of the present disclosure. In FIG. 6A, the second conductive layer 440 is deposited on the MIM dielectric layer 430 that is on the first conductive layer 420. A portion 442 of the second conductive layer 440 is deposited on the portion 432 of the MIM dielectric layer 430. The second conductive layer 440 may be formed by a copper (CU) deposition. The CU deposition may deposit copper on the MIM dielectric layer 430 to fill a remaining portion of the trench 410 defined by the MIM dielectric layer 430. Although a CU deposition is described, other conductive materials are also contemplated for the second conductive layer 440.

FIG. 6B further illustrates fabrication of the BEOL sidewall MIM capacitor 400 of FIG. 4, according to aspects of the present disclosure. In FIG. 6B, the portion 442 of the second conductive layer 440 is processed to expose the portion 432 of the MIM dielectric layer 430 that is on the portion 422 of the first conductive layer 420. The portion 432 of the MIM dielectric layer 430 may be exposed by a chemical mechanical polish (CMP) of the portion 442 of the second conductive layer 440. Although a CMP process is described, other processes are also contemplated to expose the portion 432 of the MIM dielectric layer 430.

FIG. 6C further illustrates fabrication of the BEOL sidewall MIM capacitor 400 of FIG. 4, according to aspects of the present disclosure. In FIG. 6C, an optional protection dielectric 434 is deposited on an exposed surface of the second conductive layer 440 and the portion 432 of the MIM dielectric layer 430 that is on the portion 422 of the first conductive layer 420. A material composition of the optional protection dielectric 434 may be the same as the material composition of the MIM dielectric layer 430 and deposited using a similar deposition process.

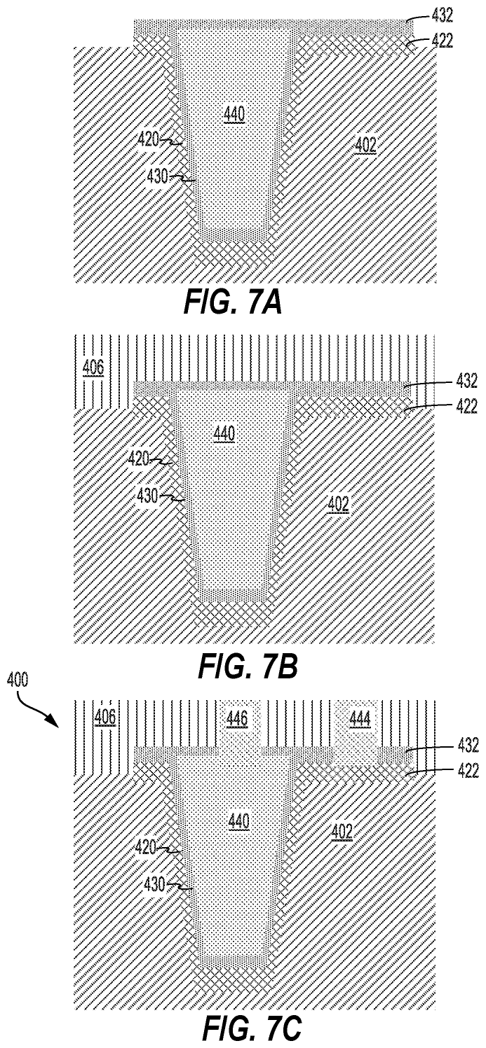

FIGS. 7A-7C further illustrate fabrication of the BEOL sidewall MIM capacitor 400 of FIG. 4, according to aspects of the present disclosure. In FIG. 7A, an etch process is performed on the portion 422 of the first conductive layer 420 and the portion 432 of the MIM dielectric layer 430 to expose portions of the surface of the ILD 402. In FIG. 7B, the IMD layer 406 is deposited on the portion 422 of the first conductive layer 420, the portion 432 of the MIM dielectric layer 430, and exposed portions of the surface of the ILD 402. In FIG. 7C, the first terminal 444 is formed that is coupled to the portion 422 of the first conductive layer 420 through the portion 432 of the MIM dielectric layer 430 on the surface of the ILD 402. In addition, the second terminal 446 is formed that is coupled to the second conductive layer 440 of the BEOL sidewall MIM capacitor 400.

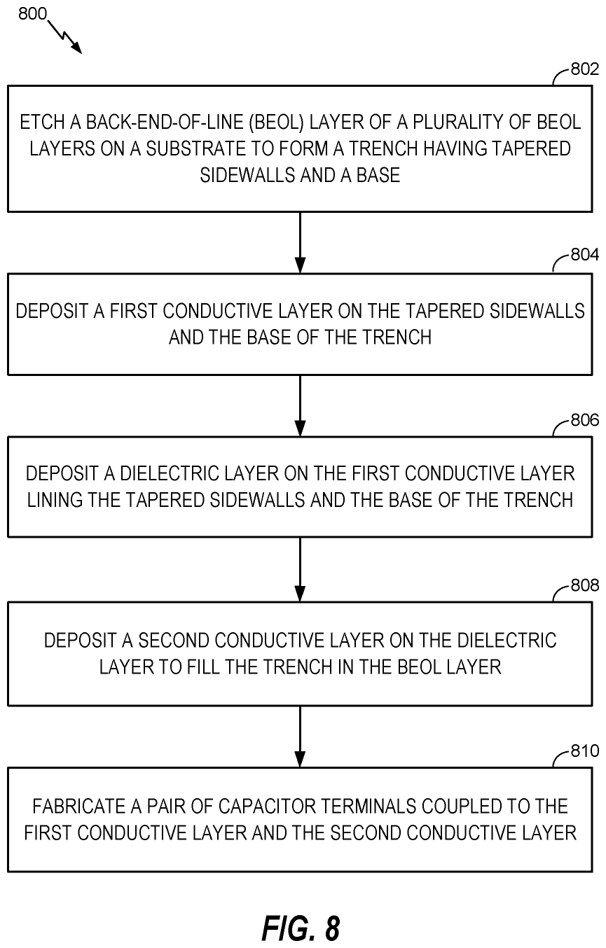

FIG. 8 is a process flow diagram illustrating a method for fabricating a back-end-of-line (BEOL) sidewall metal-insulator-metal (MIM) capacitor, according to an aspect of the present disclosure. A method 800 begins in block 802, in which a BEOL layer of multiple BEOL layers on a substrate is etched to form a trench having tapered sidewalls and a base in the BEOL layer. For example, as shown in FIG. 7A, a trench 410 is formed by etching an ILD 402 (e.g., BEOL layer) according to a deposited sidewall MIM capacitor (SMC) mask (not shown). In this example, the trench 410 includes a base 412 and tapered sidewalls (e.g., 414 and 416). In block 804, a first conductive layer is deposited on the tapered sidewalls and the base of the trench. For example, as shown in FIG. 7B, a first conductive layer 420 is deposited on the tapered sidewalls (e.g., 414 and 416) as well as the base 412 of the trench 410.

In block 806, a dielectric layer is deposited on the first conductive layer lining the tapered sidewalls and the base of the trench. As shown in FIG. 5C, a MIM dielectric layer 430 is deposited on the first conductive layer 420 that is on the tapered sidewalls (e.g., 414 and 416) as well as the base 412 of the trench 410. In block 808, a second conductive layer is deposited on the dielectric layer to fill the trench in the BEOL layer. As shown in FIG. 6A, a second conductive layer 440 is deposited on the MIM dielectric layer 430 that is on the first conductive layer 420 to fill a remaining opening of the trench 410 in the ILD 402.

Referring again to FIG. 8, in block 810, a pair of capacitor terminals are fabricated to couple to the first conductive layer and the second conductive layer. For example, as shown in FIG. 7C, the first terminal 444 is formed to couple to the portion 422 of the first conductive layer 420 through the portion 432 of the MIM dielectric layer 430 on the surface of the ILD 402. In addition, the second terminal 446 is formed to couple to the second conductive layer 440 of the BEOL sidewall MIM capacitor 400. It is noted that the BEOL sidewall MIM capacitor can be formed at the same time as when other BEOL metals are formed.

According to a further aspect of the present disclosure, an IC includes a BEOL sidewall MIM capacitor. In one configuration, the IC has means for supporting BEOL layers. In one configuration, the supporting means may be the substrate 102/202/402, as shown in FIGS. 1-4. In another aspect, the aforementioned means may be any structure or any material configured to perform the functions recited by the aforementioned means.

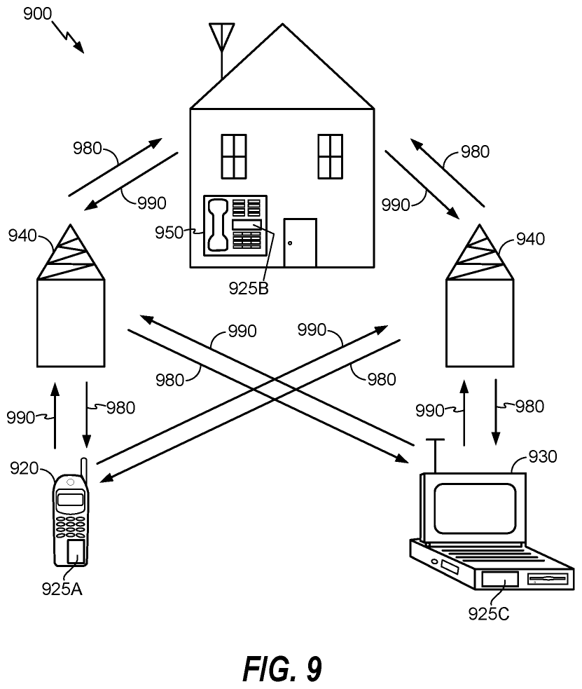

FIG. 9 is a block diagram showing an exemplary wireless communications system 900 in which an aspect of the present disclosure may be employed. For purposes of illustration, FIG. 9 shows three remote units 920, 930, and 950 and two base stations 940. It will be recognized that wireless communications systems may have many more remote units and base stations. Remote units 920, 930, and 950 include IC devices 925A, 925C, and 925B that include the disclosed BEOL sidewall MIM capacitor. It will be recognized that other devices may also include the disclosed BEOL sidewall MIM capacitor, such as the base stations, switching devices, and network equipment. FIG. 9 shows forward link signals 980 from the base stations 940 to the remote units 920, 930, and 950 and reverse link signals 990 from the remote units 920, 930, and 950 to the base stations 940.

In FIG. 9, remote unit 920 is shown as a mobile telephone, remote unit 930 is shown as a portable computer, and remote unit 950 is shown as a fixed location remote unit in a wireless local loop system. For example, the remote units may be a mobile phone, a hand-held personal communication systems (PCS) unit, a portable data unit, such as a personal digital assistant (PDA), a GPS enabled device, a navigation device, a communications device, a set top box, a music player, a video player, an entertainment unit, a fixed location data unit, such as meter reading equipment, or other device that stores or retrieves data or computer instructions, or combinations thereof. Although FIG. 9 illustrates remote units according to the aspects of the present disclosure, the present disclosure is not limited to these exemplary illustrated units. Aspects of the present disclosure may be suitably employed in many devices, which include the disclosed BEOL sidewall MIM capacitor.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code in the form of instructions or data structures and that can be accessed by a general-purpose or special-purpose computer, or a general-purpose or special-purpose processor. In addition, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk, and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An integrated circuit (IC), comprising:
a substrate;
a plurality of back-end-of-line (BEOL) layers on the substrate;
a trench having tapered sidewalls and a base in a BEOL layer of the plurality of BEOL layers on the substrate; and
a metal-insulator-metal (MIM) capacitor on the tapered sidewalls and the base of the trench in the BEOL layer, comprising:
a first conductive layer to line the tapered sidewalls and the base of the trench;
a dielectric layer to line the first conductive layer on the tapered sidewalls and the base of the trench; and
a second conductive layer on the dielectric layer and filling the trench in the BEOL layer.

2. The IC of claim 1, in which the first conductive layer comprises aluminum and the second conductive layer comprises copper.

3. The IC of claim 1, in which an angle of a first tapered sidewall of the trench is in a range of seventy degrees (70°) to eighty degrees (80°).

4. The IC of claim 3, in which an angle of a second tapered sidewall of the trench is in a range of one-hundred degrees (100°) to one-hundred ten degrees (110°).

5. The IC of claim 1, in which a volume of the second conductive layer is greater than a volume of the first conductive layer.

6. The IC of claim 1, in which the second conductive layer comprises a conductive plug having a first portion within the BEOL layer, the first portion of the conductive plug surrounded by the first conductive layer and the dielectric layer.

7. The IC of claim 6, in which the conductive plug comprises a second portion outside the BEOL layer.

8. The IC of claim 1, further comprising:
a first terminal coupled to the first conductive layer through the dielectric layer on the first conductive layer; and
a second terminal coupled to the second conductive layer through a dielectric protection layer on the second conductive layer.

9. The IC of claim 8, further comprising an inter-metal dielectric (IMD) layer on the first terminal, the second terminal, and an exposed surface of the BEOL layer, in which the first terminal and the second terminal are exposed through the IMD layer.

10. The IC of claim 1, integrated into a radio frequency (RF) integrated circuit (RFIC) chip, the RFIC chip incorporated into at least one of a music player, a video player, an entertainment unit, a navigation device, a communications device, a personal digital assistant (PDA), a fixed location data unit, a mobile phone, and a portable computer.

11. A method for fabricating a back-end-of-line (BEOL) sidewall metal-insulator-metal (MIM) capacitor, comprising:
etching a BEOL layer of a plurality of BEOL layers on a substrate to form a trench having tapered sidewalls and a base;
depositing a first conductive layer on the tapered sidewalls and the base of the trench;
depositing a dielectric layer on the first conductive layer to line the tapered sidewalls and the base of the trench;
depositing a second conductive layer on the dielectric layer to fill the trench in the BEOL layer; and
fabricating a pair of capacitor terminals coupled to the first conductive layer and the second conductive layer.

12. The method of claim 11, in which depositing the second conductive layer comprises depositing a volume of the second conductive layer greater than a volume of the first conductive layer.

13. The method of claim 11, in which depositing the second conductive layer comprises depositing a first portion of the second conductive layer within the BEOL layer, surrounded by the first conductive layer and the dielectric layer.

14. The method of claim 13, in which depositing the second conductive layer further comprises depositing a second portion of the second conductive layer outside the BEOL layer.

15. The method of claim 11, in which fabricating the pair of capacitor terminals comprises:
fabricating a first terminal coupled to the first conductive layer through the dielectric layer on the first conductive layer; and
fabricating a second terminal coupled to the second conductive layer through a dielectric protection layer on the second conductive layer.

16. The method of claim 15, further comprising:
depositing an inter-metal dielectric (IMD) layer on the first terminal, the second terminal, and an exposed surface of the BEOL layer; and
etching the IMD layer to expose the first terminal and the second terminal.

17. The method of claim 11, in which an angle of a first tapered sidewall of the trench is in a range of seventy degrees (70°) to eighty degrees (80°).

18. The method of claim 17, in which an angle of a second tapered sidewall of the trench is in a range of one-hundred degrees (100°) to one-hundred ten degrees (110°).

19. The method of claim 11, further comprising integrating the BEOL sidewall MIM capacitor into a radio frequency (RF) integrated circuit (RFIC) chip, the RFIC chip incorporated into at least one of a music player, a video player, an entertainment unit, a navigation device, a communications device, a personal digital assistant (PDA), a fixed location data unit, a mobile phone, and a portable computer.
